(19) United States
(12) Patent Application Publication
(10) Pub. No.: US 2016/0079076 A1
(43) Pub. Date: Mar. 17, 2016

(54) PATTERN FORMING METHOD AND SEMICONDUCTOR DEVICE MANUFACTURING METHOD

(71) Applicant: KABUSHIKI KAISHA TOSHIBA, Tokyo (JP)

(72) Inventors: HIROSHI YAMAMOTO, KUWANA (JP); TSUBASA IMAMURA, KUWANA (JP); MITSUHIRO OMURA, KUWANA (JP)

(21) Appl. No.: 14/573,057

(22) Filed: Dec. 17, 2014

(30) Foreign Application Priority Data
Sep. 12, 2014 (JP) 2014-186556

(51) Int. Cl. H01L 21/308; H01L 21/027; H01L 21/02

(52) U.S. Cl. CPC H01L 21/3081; H01L 21/02288; H01L 21/3086; H01L 21/0274

(57) ABSTRACT

According to one embodiment, a pattern forming method is provided. The method includes making a template touch resist material to form a first resist layer. The template has a recess/protrusion pattern. The method includes making a template touch resist material to form a second resist layer. The template has a recess/protrusion pattern. The method includes etching a processing object having the first resist layer and the second resist layer formed thereon. In forming the first resist layer, the template is kept at a position where a distance between a protrusion of the recess/protrusion pattern and the processing object takes on a first length. In forming the second resist layer, the template is kept at a position where a distance between a protrusion of the recess/protrusion pattern and the processing object takes on a second length. The second length is different from the first length.

### CROSS-REFERENCE TO RELATED APPLICATIONS

This application is based upon and claims the benefit of priority from Japanese Patent Application No. 2014-186556, filed on Sep. 12, 2014; the entire contents of which are incorporated herein by reference.

### FIELD

Embodiments described herein relate generally to a pattern forming method and a semiconductor device manufacturing method.

### BACKGROUND

Nano-imprint lithography is one of fine structure forming methods used in the manufacturing process of semiconductor devices. Many of resist materials used in nano-imprint lithography are weaker in resistance to plasma than resist materials used in usual photolithography. In the nano-imprint lithography, the shapes of pattern features in the resist layer may degrade due to the influence of ion impacts. This shape degradation may cause variations in dimensions of pattern features in the resist layer. If there are variations in dimensions in the resist layer as a mask in etching an object being processed, it is difficult to form a uniformly-dimensioned pattern in the object to processing.

### BRIEF DESCRIPTION OF THE DRAWINGS

FIG. 1 is an equivalent circuit diagram showing part of a memory cell array formed in the memory cell area of a NAND flash memory device, to which an embodiment is applied;

FIG. 2 is a plan view showing part of the layout pattern of the memory cell area of the NAND flash memory device, to which the embodiment is applied;

FIG. 3 is a cross-sectional view along line A-A of the layout pattern shown in FIG. 2; and

FIGS. 4A to 4H are cross-sectional views showing the procedure of a pattern forming method of the embodiment.

### DETAILED DESCRIPTION

In general, according to one embodiment, a pattern, farming method is provided. The method includes making a template touch resist material supplied onto a first area of a processing object to form a first resist layer on the first area. The template has a recess/protrusion pattern. The method includes making a template touch resist material supplied onto a second area of the processing object to form a second resist layer on the second area. The template has a recess/protrusion pattern. The method includes etching the processing object having the first resist layer and the second resist layer formed thereon. In forming the first resist layer, the template is kept at a position where a distance between a protrusion of the recess/protrusion pattern and the processing object takes on a first length. In forming the second resist layer, the template is kept at a position where a distance between a protrusion of the recess/protrusion pattern and the processing object takes on a second length. The second length is different from the first length.

Exemplary embodiments of a pattern forming method and a semiconductor device manufacturing method will be explained below in detail with reference to the accompanying drawings. The present invention is not limited to the following embodiments.

The cross-sectional views of a semiconductor device used in the embodiment below are schematic, and relations between the thicknesses and widths of layers, the proportions of one thicknesses of the layers, and the like may be different from actual ones. Further, the film thicknesses shown below are illustrative, and the film thicknesses are not limited to those examples.

### Embodiment

The pattern forming method according to the embodiment is applied to the manufacture of a NAND flash memory device that is a nonvolatile semiconductor storage device. Before the description of the pattern forming method, the configuration of the NAND flash memory device will be described.

The NAND flash memory device comprises a memory cell area and a peripheral circuit area. In the memory cell area, a multitude of memory cell transistors are arranged in a matrix. The peripheral circuit area includes peripheral-circuit transistors. The peripheral-circuit transistors drive the memory cells. in the description below, the memory cell transistor is also called a memory cell.

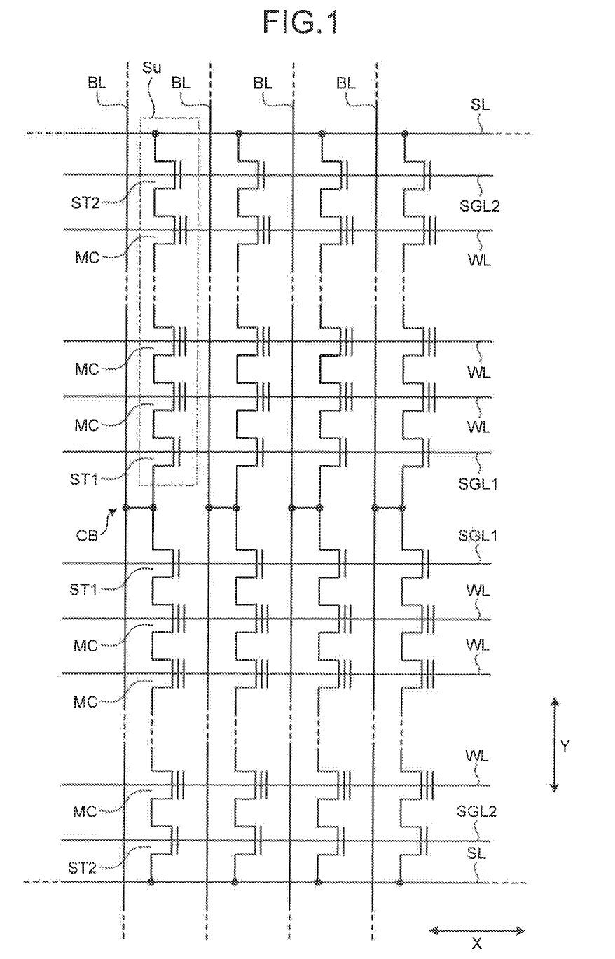

FIG. 1 is an equivalent circuit diagram showing part of a memory cell array formed in the memory cell area of the NAND flash memory device, to which the embodiment is applied. The memory cell array comprises NAND cell units (memory units) Su arranged in columns.

The NAND cell unit Su comprises two selector gate transistors ST1, ST2 and a memory cell column. The memory cell column comprises a plurality of memory cells MC. For example, 2² number of memory cells MC, where n is a positive integer, are connected in series between the selector gate transistors ST1, ST2. In the NAND cell unit Su, adjacent memory cells MC shares a source/drain region.

The X direction shown in FIG. 1 corresponds to a word line direction and a gate width direction. The memory cells MC arranged along the X direction are connected to a common word line (control gate line) WL. The selector gate transistors ST1 arranged along the X direction are connected to a common selector gate line SGL1. The selector gate transistors ST2 arranged along the X direction are connected to a common selector gate line SGL2.

The Y direction shown in FIG. 1 is perpendicular to the X direction. The Y direction corresponds to a bit line direction and a gate length direction. A bit line contact CB is connected to the drain region of the selector gate transistor ST1. One end of the bit line contact CB is connected to a bit line BL. The bit line BL extends along the Y direction. The selector gate transistor ST2 is connected to a source line SL via the source region. The source line SL extends along the X direction.

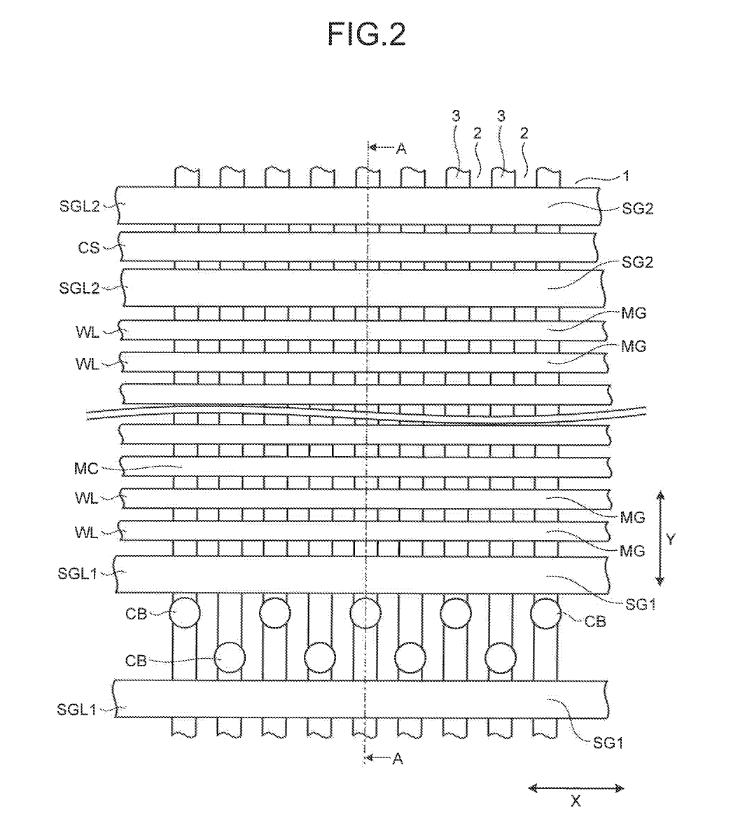

FIG. 2 is a plan view showing part of the layout pattern of the memory cell area of the NAND flash memory device, to which the embodiment is applied. A semiconductor substrate 1 comprises a plurality of STIs (Shallow Trench Isolations) 2 extending along the Y direction. The STIs 2 are element isolation regions. The STIs 2 are formed at predetermined intervals along the X direction.

An active region 3 is located adjacent to the STI 2. A plurality of active regions 3 are isolated in the X direction from each, other via the STIs 2. The word lines WL of the memory cells MC are formed at predetermined intervals along the Y direction. The word lines WL form a line-and-space pattern.

Two adjacent selector gate lines SGL1 are formed in parallel. The selector gate lines SGL1 extend along the X direction. Bit line contacts CB are respectively formed on the active regions 3 between two selector gate lines SGL1. In this example, the position of the bit line contact CB along the Y direction is different between adjacent active regions 3. Bit line contacts CB nearer one of the selector gate lines SGL1 and bit line contacts CB nearer the other selector gate line SGL1 are alternately placed between the two selector gate lines SGL1.

Two adjacent selector gate lines SGL2 are formed in parallel. The selector gate lines SGL2 extend along the X direction. Source line contacts CS are placed on the active regions 3 between the two selector gate lines SGL2.

The laminated gate structure MG of the memory cell MC is formed on an active region 3 at the place where it intersects a word line WL. The gate structures SG1, SG2 of the selector gate transistors ST1, ST2 are formed on an active region 3 at the places where it intersects selector gate lines SGL1, SGL2.

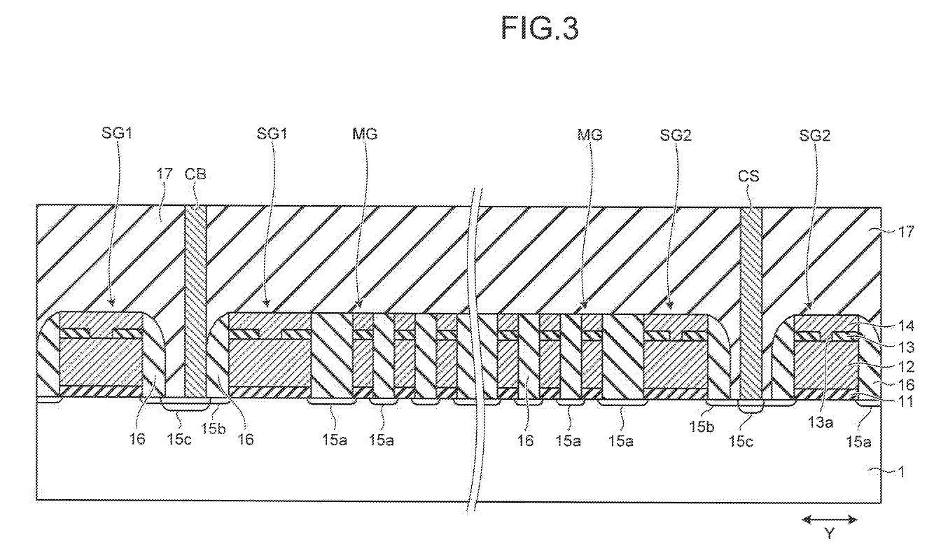

FIG. 3 is a cross-sectional view along line A-A of the layout pattern shown in FIG. 2. FIG. 3 shows the gate structures SG1, SG2 of the selector gate transistors ST1, ST2 and the laminated gate structures MG of the memory cells MC placed between the selector gate transistors ST1, ST2 in the active region 3.

The laminated gate structures MG and the gate structures SG1, SG2 are formed on the semiconductor substrate 1 such as a silicon substrate. The laminated gate structures MG and the gate structures SG1, SG2 each comprise a floating gate electrode film 12, an inter-electrode insulating film 13, and a control gate electrode film 14. The floating gate electrode film 12 is laid on a tunnel insulating film 11 formed on the semiconductor substrate 1. The inter-electrode insulating film 13 and the control gate electrode film 14 are sequentially laid one over the other on the floating gate electrode film 12.

Openings 13a are termed in the inter-electrode insulating film 13 of the gate structures SG1, SG2. The control gate electrode film 14 is filled into the openings 13a. The floating gate electrode film 12 and the control gate electrode film 14 conductively communicate via the opening 13a. In the selector gate transistors ST1, ST2, the floating gate electrode film 12 and the control gate electrode film 14 form a gate electrode.

The tunnel insulating film 11 is a thermal oxide film, a thermal oxide nitride film, a CVD (Chemical Vapor Deposition) oxide film, a CVD oxide nitride film, a Si-sandwiched insulating film, an insulating film having Si embedded like dots therein, or the like. The floating gate electrode film 12 is a polycrystalline silicon having an N-type impurity or P-type impurity doped therein, a metal film or polymetal film using Mo, Ti, W, Al, Ta, etc., a nitride film or the like.

The inter-electrode insulating film 13 is a silicon oxide film, a silicon nitride film, an ONO (Oxide-Nitride-Oxide) film, a high dielectric constant film, and a laminated structure of a low dielectric constant film and a high dielectric constant film, or the like. The ONO film is a laminated structure of silicon oxide films and a silicon nitride film. The high dielectric constant film is an aluminum oxide film and a hafnium oxide film, or the like. The low dielectric constant film is a silicon oxide film and a silicon nitride film, or the like.

The control gate electrode film 14 is a polycrystalline silicon having an N-type impurity or P-type impurity doped therein, a metal film or polymetal film using Mo, Ti, W, Al, Ta, etc., a laminated structure of a polycrystalline silicon film and a metal silicide film, or the like.

Impurity-diffused regions 15a are formed in the surfaces of parts of the semiconductor substrate 1 between laminated gate structures MG and MG and between a laminated gate structure MG and gate structures SG1, SG2. The impurity-diffused regions 15a are source/drain regions. Impurity-diffused regions 15b are formed in the surfaces of parts of the semiconductor substrate 1 between adjacent gate structures SG1 and SG1 and between SG2 and SG2. The impurity-diffused regions 15b are source/drain regions.

A side wall insulating film 16 is formed between each pair of adjacent laminated gate structures MG and MG and between a laminated gate structure MG and gate structures SG1, SG2. Parts of the side wall insulating film 16 are formed on the side wall surfaces of the gate structures SG1 between adjacent gate structures SG1 and SG1. Parts of the side wall insulating film 16 are formed on the side wall surfaces of the gate structures SG2 between adjacent gate structures SG2 and SG2.

Impurity-diffused regions 15c are formed in tine surfaces of parts of the semiconductor substrate 1 between parts facing each other of the side wall insulating film 16 between gate structures SG1 and SG1 and between SG2 and SG2. The impurity-diffused regions 15c decrease the contact resistance of the bit line contacts CB and the source line contacts CS. The impurity-diffused region 15c is narrower in width than she impurity-diffused region 15b. The impurity-diffused region 15c is deeper in diffusion depth (pn junction depth) than the impurity-diffused region 15b. The impurity-diffused region 15c has an LDD (Lightly Doped Drain) structure.

An inter-layer insulating film 17 is formed over the laminated gate structures MG and the gate structures SG1, SG2 having the side wall insulating film 16 formed thereon. The bit line contact CB is formed between the gate structures SG1 and SG1 placed at one ends of columns of memory cells MC. The source line contact CS is formed between the gate structures SG2 and SG2 placed at the other ends of columns of memory cells MC.

The bit line contact CB extends through between the upper surface of the inter-layer insulating film 17 and the surface of the semiconductor substrate 1. The bit line contact CB is nearer one of the two gate structures SG1 than the other. The source line contact CS extends through between the upper surface of the inter-layer insulating film 17 and the surface of the semiconductor substrate 1. The source line contacts CS below cross the bit lines BL. The structure of the memory cells shown in FIG. 3 is illustrative.

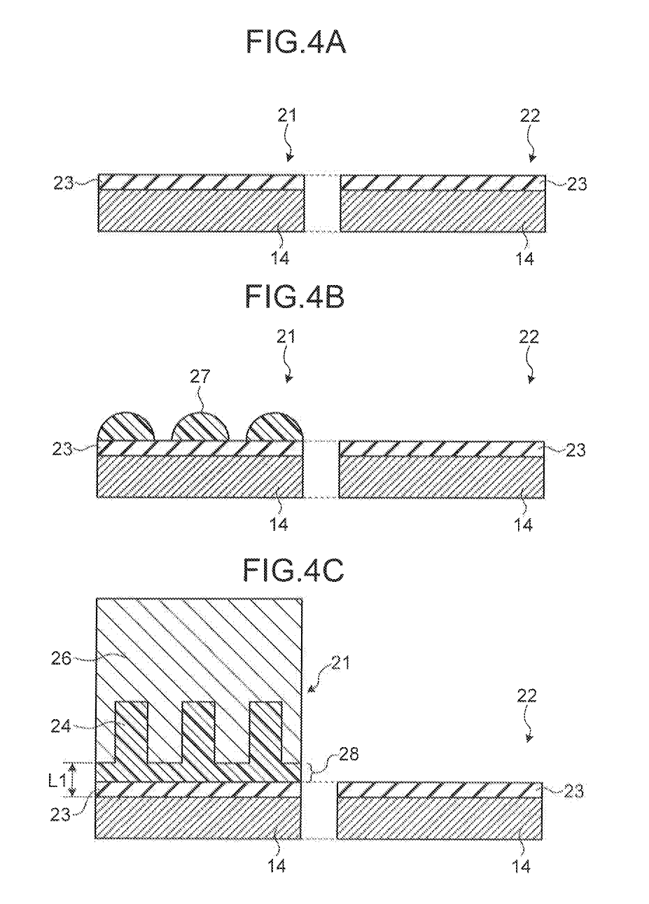

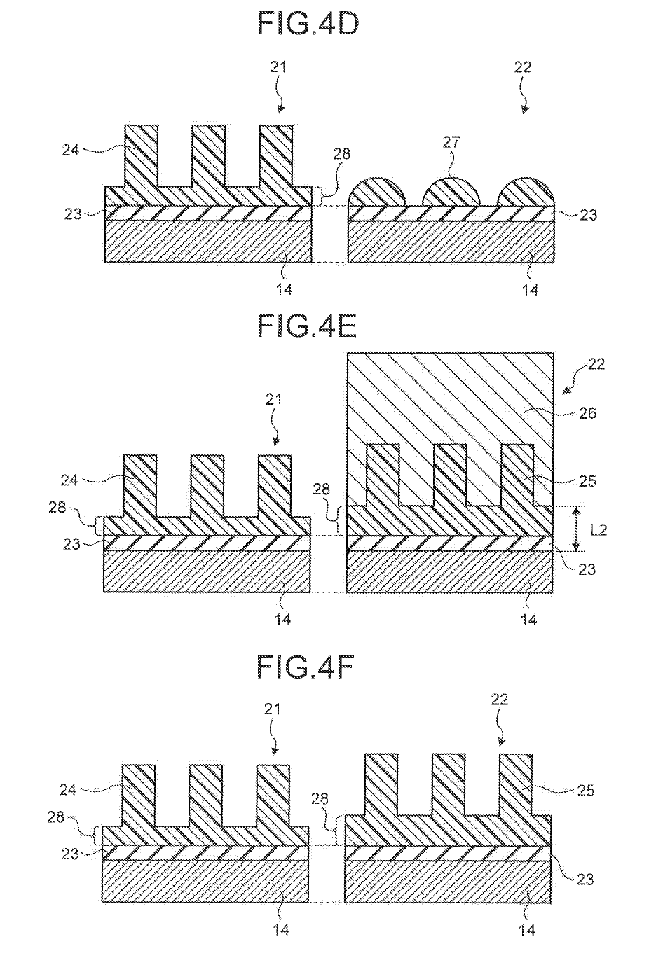

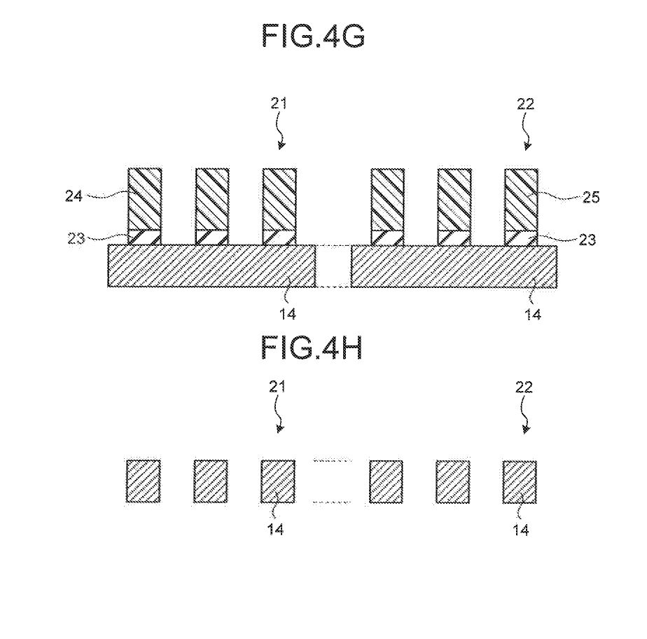

Next, the pattern forming method in the manufacturing process of the NAND flash memory device will be described. FIGS. 4A to 4H are cross-sectional views showing the procedure of the pattern forming method of the embodiment. The pattern forming method of the embodiment is nano-imprint lithography.

First, the tunnel insulating film and the floating gate electrode film are formed over a wafer that is a semiconductor substrate. Trenches are formed extending to the semiconductor substrate by photolithography technique and etching technique such as an RIE method. These trenches extend along the Y direction (bit line direction) and are formed at predetermined intervals along the X direction (word line direction).

Then an insulating film such as a silicon oxide film is filled into the trenches to form STIs. Then the inter-electrode insulating film is formed over the entire surface of the semiconductor substrate, and openings are formed extending through the inter-electrode insulating film in the regions where the selector gate lines SGL1, SGL2 are to be formed, using photolithography technique and etching technique. Then the control gate electrode film 14 is formed over the entire surface of the semiconductor substrate.

In the pattern forming method of the embodiment, processing objects are the tunnel insulating film, the floating gate electrode film, the inter-electrode insulating film, and the control gate electrode film 14 formed over the semiconductor substrate. FIGS. 4A to 4H show the control gate electrode film 14 that is the uppermost layer from among the processing objects. Si is used as the control gate electrode film 14.

It is assumed that, under processing conditions in the embodiment, resist layers formed over the wafer are subject, to the influence of ion impacts more strongly at positions near the outer edge of the wafer than near the center.

The control gate electrode film 14 shown in FIG. 4A is formed over the entire surface of the wafer that is a semiconductor substrate. FIGS. 4A to 4H show two portions 21, 22 of the control gate electrode film 14 formed over the entire surface of the wafer.

In the embodiment, on each of multiple imprint areas (shot areas) in the surface of a processing object, the pattern of a resist layer is formed. One of imprint areas located in the center of the surface of the processing object is named the first area. One of imprint areas located in the outer edge of the surface of the processing object is named the second area. The portion 21 is a part of the first area. The portion 22 is a part of the second area.

As shown in FIG. 4A, a closely-adhering layer 23 is formed over the entire surface of the control gate electrode film 14 that is a processing object. The closely-adhering layer 23 improves the adhesion of the control gate electrode film 14 and a resist layer described later. The closely-adhering layer 23 is made of organic material.

FIGS. 4B to 4D show the procedure of forming a resist layer 24 on the first area. As shown in FIG. 4B, resist material 27 is dropped, onto the entire first area including the portion 21. The resist material 27 is a photo-curing liquid, resist material. The resist material 27 is dropped at intervals by an ink jet method. The amount of the resist material 27 to be dropped is controlled to be such an amount as to be able to form the resist layer having a desired pattern.

Immediately after the resist material 27 is supplied onto the first area, a template 26 is made to touch the resist material 27. The template 26 has a line-and-space-like recess/protrusion pattern. The template is made of quartz material.

The template 26 descends with the surface in which the recess/protrusion pattern is formed facing the resist material 27. The template 26 further descends after the tops of the protrusions of the recess/protrusion pattern reach the resist material 27. As shown in FIG. 4C, the template 26 descends until the distance between the tops of the protrusions and the control gate electrode film 14 that is a processing object takes on a first length L1. FIG. 4C shows part of the template 26 facing the portion 21.

Ultraviolet rays are irradiated onto the resist material 27 through, the template 26 while keeping the template 26 in the position where the distance between the template 26 and the control gate electrode film 14 takes on the first length L1. After the resist material 27 is cured by ultraviolet ray irradiation, the template 26 is raised to be removed from the resist material 27.

Thus, as shown in FIG. 4D, the resist layer 24 having the recess/protrusion pattern transferred from the template 26 therein is formed. The resist layer 24 has the line-and-space-like recess/protrusion pattern. The resist layer 24 is a first resist layer formed on the first area.

By keeping the template 26 in the position where the distance between the template 26 and the control gate electrode film 14 takes on the first length L1, the resist material 27 is filled between the tops of the protrusions of the template 26 and the closely-adhering layer 23. Thus, the resist layer 24 including a resist residual film 28 is formed. The resist residual film 28 is a layer-like portion of the resist layer 24 from the bottom surfaces of its recesses to its surface touching the closely-adhering layer 23. The recess/protrusion pattern of the resist layer 24 is formed on the resist residual film 28.

The formation of the resist residual film 28 reduces damage to the template 26 due to being pressed against the processing object. Further, the formation of the resist residual film 28 reduces bubbles, in number, remaining in the resist material 27 filled between the template 26 and the closely-adhering layer 23.

FIGS. 4D to 4F show the procedure of forming a resist layer 25 on the second area. As shown in FIG. 4D, resist material 27 is dropped onto the entire second area including the portion 22. Immediately after the resist material 27 is supplied onto the second area, the template 25 is made to touch the resist material 27.

As shown in FIG. 4E the template 26 descends until the distance between the tops of the protrusions and the control gate electrode film 14 that is a processing object takes on a second length L2. It is supposed that the second length L2 is longer than the first length L1. The relation, L2>L1, holds. FIG. 4E shows part of the template 26 facing the portion 22.

Ultraviolet rays are irradiated onto the resist material 27 through the template 26 while keeping the template 26 in the position where the distance between the template 26 and the control gate electrode film 14 takes on the second length L2. After the resist material 27 is cured by ultraviolet ray irradiation, the template 26 is raised to be removed from the resist material 27.

Thus, as shown in FIG. 4F, the resist layer 25 having the recess/protrusion pattern transferred from the template 26 therein is formed. The resist layer 25 has the line-and-space-like recess/protrusion pattern. The resist layer 25 is at second resist layer formed on the second area.

By keeping the template 26 in the position where the distance between the template 26 and the control gate electrode film 14 takes on the second, length L2, the resist material 27 is filled between the tops or the protrusions of the template 26 and the closely-adhering layer 23. Thus, the resist layer 25 including a resist residual film 28 is formed. The resist residual film 28 is a layer-like portion of the resist layer 25 from the bottom surfaces of its recesses to its surface touching the closely-adhering layer 23. The recess/protrusion pattern of the resist layer 25 is formed on the resist residual film 28.

The thickness of the resist residual film 28 is controlled according to the distance between the processing object and the template 26 when the template 26 is lowered. By setting such that L2>L1, the thickness of the resist residual film 28 of the resist layer 25 becomes greater than that of the resist residual film 28 of the resist layer 24. Letting TH1 be the thickness of the resist residual film 28 of the resist layer 24 and TH2 be the thickness of the resist residual film 28 of the resist layer 25, the relation, TH2>TH1, holds.

The resist residual film 28 is formed to be thicker on imprint areas near the outer edge of the surface of the processing object than on imprint areas near the center. The thickness of the resist residual film 28 is adjusted according to the position of the imprint area. In order to adjust the thickness of the resist residual film 28, the interval at which the resist material 27 is dropped may be controlled. If the thickness of the resist residual film 28 is intended to increase, the interval between drops of the resist material 27 is adjusted so that the density of dropped resist material 27 becomes higher.

If it is intended that L2>L1, the interval between drops of the resist material 27 dropped onto the second area is shorter than that of the resist material 27 drooped onto the first area. Thus, the thickness of the resist residual film 28 of the resist layer 25 is greater than that of the resist residual film 28 of the resist layer 24.

The resist layer is formed on each imprint area in the same way as on the first and second areas. The procedures of dropping the resist material 27, lowering the template 25, curing the resist material 27, and removing the template 26 are repeated for each imprint area. Under processing conditions in the embodiment, the distance between the protrusions of the template 26 and the processing object is set greater for imprint areas near the outer edge of the surface of the processing object than for imprint areas near the center.

After the formation of the pattern of the resist layer finishes for ail the imprint areas in the surface of the processing object, anisotropic etching is performed with the resist layers as a mask. In the embodiment, dry etching such as RIE (Reactive Ion Etching) is performed as anisotropic etching.

Under processing conditions in the embodiment, the etching of the resist layer progresses faster at areas near the outer edge of the surface of the processing object than at areas near the center. The etching of the resist layer 25 on the second area progresses faster than that of the resist layer 24 on the first area.

By setting such that TH2>TH1, the amount of part of the resist layer 25 eliminated until the resist residual film 28 is eliminated becomes greater than the amount of part of the resist layer 24 eliminated until the resist residual film 28 is eliminated. TH1 and TH2 are decided on taking into account the difference in progression speed of the etching of the resist layers 24, 25.

With TH1 and TH2 being set appropriately according to the processing conditions, the elimination of the resist residual film 28 can finish almost simultaneously for the resist layers 24 and 25. Thus, as shown in FIG. 4G, etching reaches the surface of the control gate electrode film 14 almost simultaneously at the first and second areas.

The resist layer of each imprint area is formed to have the resist residual film 28 whose thickness is controlled appropriately according to the processing conditions. Thus, the etching of the control gate electrode film 14 can be made to begin almost simultaneously at the imprint areas.

The etching of the control gate electrode film 14 begins almost simultaneously at the first and second areas. Thus, as shown in FIG. 4H, the control gate electrode film 14 having a uniformly-dimensioned pattern at the first and second areas can be obtained. Through etching of layers that are processing objects, the layers are patterned to form a wiring pattern of word lines. The word lines form a line-and-space pattern.

As at the first and second areas, the etching of the control gate electrode film 14 begins at almost the same time at each imprint area. Thus, a uniformly-dimensioned pattern can be formed in the processing object over the entire wafer.

In the case where the influence of ion impacts that the resist layer is subject to is weaker at positions near the outer edge of the wafer than at positions near the center, the second length L2 is set shorter than the first length L1. By setting such that L1>L2, the thickness of the resist residual film 28 of the resist layer 25 becomes smaller than that of the resist residual film 28 of the resist layer 24. Even in this case, a uniformly-dimensioned pattern can be formed in the processing object at the first and second areas. The relation between the first length L1 and the second length L2 can be changed according to the processing conditions provided that the first length L1 and the second length L2 may be different.

If it is intended that L1>L2, the interval between drops of the resist material 27 dropped onto the second area is preferably longer than that of the resist material 27 dropped onto the first area. Thus, the thickness of the resist residual film 28 of the resist layer 25 is smaller than that of the resist residual film 28 of the resist layer 24. The relation between the interval between drops of the resist material 27 in the first area and the interval between drops of the resist material 27 in the second area can be changed according to the relation between the first length L1 and the second length L2. The interval between drops of the resist material 27 in the first area and that of the resist material 27 in the second area is preferably set different in length.

Instead of setting the interval between drops of the resist material 27 to be different between the first and second areas, the amount of the resist material 27 ejected in a drop jetted by an ink jet may be set to be different between the first and second areas. If it is intended that L2>L1, the amount of the resist material 27 ejected in a drop for the second area is set larger than that for the first area. If it is intended that L1>L2, the amount of the resist material 27 ejected in a drop for the second area is set smaller than that for the first area. Also in this case, the first and second resist layers having the resist residual film 28 of a thickness different between the two can be formed.

The force of pressing the template 26 in forming the first resist layer and the force of pressing the template 26 in forming the second resist layer may be set to be different. If it is intended that L2>L1, the force of pressing the template 26 for the second area is set weaker than the force of pressing the template 26 for the first area. If it is intended that L1>L2, the force of pressing the template 26 for the second area is set stronger than the force of pressing the template 26 for the first area. Also in this case, the first and second resist layers having the resist residual film 28 of a thickness different between the two can be formed.

The light amount of ultraviolet rays to be irradiated onto the resist material 27 in forming the first resist layer and the light amount of ultraviolet rays to be irradiated, onto the resist material 27 in forming the second resist layer may be set to be different. By reducing the light amount of ultraviolet rays irradiated onto the resist material 27, the curing of the resist material 27 is made slower.

If the light amount of ultraviolet rays in forming the second resist layer is set larger than the light amount of ultraviolet rays in forming the first resist layer, the hardness of the second resist layer becomes higher than the hardness of the first resist layer. By this means, the progression of etching of the second resist layer is made slower than the progression of etching of the first resist layer.

If the light amount of ultraviolet rays in forming the second resist layer is set smaller than the light amount of ultraviolet rays in forming the first resist layer, the hardness of the second resist layer becomes lower than the hardness of the first resist layer. By this means, the progression of etching of the second resist layer is promoted as compared with the progression of etching of the first resist layer.

By making the thickness of the resist residual film 28 different between the first and second resist layers and also making the light amount of ultraviolet rays different, the progression of etching can be controlled so as to form a uniformly-dimensioned pattern.

The thickness of the resist residual film 28 is not limited to being uniform over an imprint area. In an imprint area, there may be parts different in the thickness of the resist residual film 28. By varying the amount of the resist material 27 ejected in a drop, the thickness of the resist residual film 28 may have a distribution over an imprint area. Or by making the distance between the protrusions of the template 26 and the processing object different over an imprint area, the thickness of the resist residual film 28 may have a distribution over the imprint area. Thus, the progression of etching over the imprint area can be controlled.

According to the pattern forming method of the embodiment, the distance between the protrusions of the template 26 and the processing object is made different in length between in forming the first resist layer and in forming the second resist layer. The resist residual film 28 of the first resist layer and the resist residual film 28 of the second resist layer are made different in thickness. By controlling the thicknesses of the resist residual films 28 of the first and second resist layers appropriately, the etching of the processing object can be made to start almost simultaneously for the first and second areas. By making the etching of the processing object start almost simultaneously for the first and second areas, a uniformly-dimensioned pattern can be formed in the processing object.

A common template 26 can be used for the first and second areas. By simple operation to control the position at which the descent of the template 26 is stopped, the processing object having a uniformly-dimensioned pattern can be obtained. As compared with the case where templates having different shapes are needed for the first and second areas respectively, adjustment for obtaining a uniformly-dimensioned pattern can be easily performed. Variations in processing over the wafer can be improved without changing the design of the template 26 according to the processing conditions.

As describe above, the pattern forming method of the embodiment has the effect that a uniformly-dimensioned pattern can be formed. Further, NAND flash memory devices having uniformly-dimensioned patterns can be manufactured. The pattern forming method of the embodiment is not limited to being applied to the manufacture of a NAND flash memory device. The pattern forming method of the embodiment may be applied to the manufacture of any semiconductor device having a line-and-space wiring pattern. The pattern forming method of the embodiment may be applied to not only processing for a wiring pattern but also processing substrates.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern forming method comprising:
making a template having a recess/protrusion pattern touch resist material supplied onto a first area of a processing object to form a first resist layer on the first area;
making a template having a recess/protrusion pattern touch resist material supplied onto a second area of the processing object to form a second resist layer on the second area; and
etching the processing object having the first resist layer and the second resist layer formed thereon,
wherein in forming the first resist layer, the template is kept at a position where a distance between a protrusion of the recess/protrusion pattern and the processing object takes on a first length, and
in forming the second resist layer, the template is kept at a position where a distance between a protrusion of the recess/protrusion pattern and the processing object takes on a second length different from the first length.

2. The pattern forming method according to claim 1, wherein the resist material is dropped at intervals, thereby being supplied onto each of the first area and the second area, and
the interval at which the resist material is dropped onto the first area and the interval at which the resist material is dropped onto the second area are different in length from each other.

3. The pattern forming method according to claim 1, wherein the resist material is supplied onto each of the first area and the second area by an ink jet, and
an amount of the resist material ejected in a drop is made different between the first area and the second area.

4. The pattern forming method according to claim 1, wherein a force of pressing the template in forming the first resist layer and a force of pressing the template in forming the second resist layer are different from each other.

5. The pattern forming method according to claim 1, wherein the resist material is photo-curing resist material, and
an amount of light to be irradiated onto the resist material, in forming the first resist layer and an amount of light to be irradiated onto the resist material in forming the second resist layer are different from each other.

6. The pattern forming method according to claim 1, wherein the first area is located in a center of a surface of the processing object,
the second area is located in an outer edge of the surface of the processing object, and
the second length is longer than the first length.

7. The pattern forming method according to claim 6, wherein the resist material is dropped at intervals, thereby being supplied onto each of the first area and the second area, and
the interval at which the resist material is dropped onto the second area is shorter than the interval at which the resist material is dropped onto the first area.

8. The pattern forming method according to claim 6, wherein the resist material is supplied onto each of the first area, and the second area by art ink jet, and
an amount of the resist material ejected in a drop onto the second area is larger than an amount of the resist material ejected in a drop onto the first area.

9. The pattern forming method according to claim 8, wherein a force of pressing the template in forming the second resist layer is weaker than a force of pressing the template in forming the first resist layer.

10. The pattern forming method according to claim 6, wherein the resist material is photo-coring resist material, and
an amount of light to be irradiated onto the resist material in forming the second resist layer is larger than an amount of light to be irradiated onto the resist material in forming the first resist layer.

11. A pattern forming method comprising:
with making a template having a recess/protrusion pattern touch photo-curing resist material supplied onto a first area of a processing object, irradiating light onto the resist material to form a first resist layer on the first area, the first area being located in a center of a surface of the processing object;
with making a template having a recess/protrusion pattern touch photo-curing resist material supplied onto a second area of the processing object, irradiating light onto the resist material to form a second resist layer on the second area, the second area being located in an outer edge of the surface of the processing object; and
etching the processing object having the first resist layer and the second resist layer formed thereon,
wherein an amount of light irradiated onto the resist material in forming the first resist layer and an amount of light irradiated onto the resist material in forming the second resist layer are different from each other.

12. The pattern forming method according to claim 11, wherein a thickness of the resist material remaining in a space between a protrusion of the recess/protrusion pattern and the processing object in forming the first resist layer and a thickness of the resist material remaining in a space between a protrusion of the recess/protrusion pattern and the processing object in forming the second resist layer are different from each other.

13. A semiconductor device manufacturing method comprising:
forming a processing object over a semiconductor substrate;
making a template having a recess/protrusion pattern touch resist material supplied onto a first area of the processing object to form a first resist layer on the first area;
after forming the first resist layer, making a template having a recess/protrusion pattern touch resist material supplied onto a second area of the processing object to form a second resist layer on the second area; and
etching the processing object having the first resist layer and the second resist layer formed thereon to form a line-and-space pattern over the semiconductor substrate,
wherein in forming the first resist layer, the template is kept at a position where a distance between a protrusion of the recess/protrusion pattern and the processing object takes on a first length, and
in forming the second resist layer, the template is kept at a position where a distance between a protrusion of the recess/protrusion pattern and the processing object takes on a second length different from the first length.

14. The semiconductor device manufacturing method, according to claim 13, wherein a thickness of the resist material remaining in a space between a protrusion of the recess/protrusion pattern and the processing object in forming the first resist layer and a thickness of the resist material remaining in a space between a protrusion of the recess/protrusion pattern and the processing object in forming the second resist layer are different from each other.

15. The semiconductor device manufacturing method according to claim 13, wherein the resist material is dropped at intervals, thereby being supplied onto each of the first area and the second area, and
the interval at which the resist material is dropped onto the first area and the interval at which the resist material is dropped onto the second area are different in length from each other.

16. The semiconductor device manufacturing method according to claim 13, wherein the resist material is supplied onto each of the first area and the second area by an ink jet, and
an amount of the resist material ejected in a drop is made different between the first area and the second area.

17. The semiconductor device manufacturing method according to claim 13, wherein a force of pressing the template in forming the first resist layer and a force of pressing the template in forming the second resist layer are different from each other.

18. The semiconductor device manufacturing method according to claim 13, wherein the resist material is photo-curing resist material, and
an amount of light to be irradiated onto the resist material in forming the first resist layer and an amount of light to be irradiated onto the resist material in forming the second resist layer are different from each other.

19. The semiconductor device manufacturing method according to claim 13, wherein the first area is located in a center of the semiconductor substrate,
the second area is located in an outer edge of the semiconductor substrate, and
the second length is longer than the first length.

20. The semiconductor device manufacturing method according to claim 13, wherein forming a line-and-space pattern over the semiconductor substrate includes eliminating, by etching, parts of the resist material remaining in a space between a top of a protrusion of the recess/protrusion pattern and the processing object after forming the first and second resist layers respectively, and patterning the processing object by etching with the first and second resist layers as a mask.
